(19) United States
(12) Patent Application Publication
(10) Pub. No.: US 2018/0206367 A1
(43) Pub. Date: Jul. 19, 2018

(54) POLYMER-BASED, WIDEBAND ELECTROMAGNETIC WAVE SHIELDING FILM

(71) Applicant: KOREA ADVANCED INSTITUTE OF SCIENCE AND TECHNOLOGY, Daejeon (KR)

(72) Inventors: Ilkwon OH, Daejeon (KR); Si Hwa LEE, Daejeon (KR)

(21) Appl. No.: 15/480,234

(22) Filed: Apr. 5, 2017

(30) Foreign Application Priority Data
Jan. 17, 2017 (KR) 10-2017-0007849

(51) Int. Cl. H05K 9/00; H01B 1/02

(52) U.S. Cl. CPC H05K 9/0083; H01B 1/023

(57) ABSTRACT

The present invention relates to a polymer-based, wideband electromagnetic wave shielding film. More particularly, the present invention relates to a polymer-based, wideband electromagnetic wave shielding film capable of improving electromagnetic wave shielding and absorption performance, by applying a multilayer graphene-nanotube-metal oxide nanostructure in which a conductive material and a magnetic material are complexly combined, as a filler of the polymer.

### TECHNICAL FIELD

The present invention relates to a polymer-based, wideband electromagnetic wave shielding film using a multilayer graphene-nanotube-metal oxide nanostructure, and more particularly, to a wideband electromagnetic wave shielding film capable of improving electromagnetic wave shielding and absorption performance, by preparing a multilayer graphene-nanotube-metal oxide nanostructure in which a conductive material and a magnetic material are complexly combined through microwave irradiation, and then applying the nanostructure as a polymer filler.

### BACKGROUND ART

Recently, as electromagnetic wave generation is increased due to rapid development and massive spread of computers, electronic products, communication devices and the like, a noise phenomenon due to electromagnetic waves in various frequency ranges is rapidly increased, thereby posing a problem that there occurs mutual interference between electronic products. In addition, electromagnetic waves emitted from electronic products may cause stress, nervous system stimulation, heart diseases and the like in the human body. The recent trend of electronic products is wearable electronics and flexible devices, and electromagnetic wave shielding materials suitable for them, which are flexible, and have durability and excellent electromagnetic wave shielding efficiency are more interested.

The electromagnetic wave shielding materials manufactured so far are largely metal-based, 1-phase carbon-based, 2-phase carbon-based, and 3-phase carbon-based. Metal-based electromagnetic wave shielding materials show high electromagnetic wave shielding efficiency, but have a limitation in that it is heavy and corrosive to moisture.

Thus, carbon-based shielding materials which are light and not corrosive to moisture were suggested. Among these carbon-based shielding materials, graphene, carbon nanotubes and the like which are the 1-phase carbon-based materials were used, but had a limitation of low shielding efficiency. As the 2-phase carbon-based materials, graphene/carbon nanotube composite materials, graphene-iron oxide composite materials and the like were used, but had problems such as a high filler content and low shielding efficiency.

Therefore, there is a need of development of a new electromagnetic wave shielding film having high shielding efficiency and durability, and being flexible, by complexly combining a conductive material and a magnetic material to synthesize an electromagnetic shielding material having high shielding efficiency and being light, and using the material.

### DISCLOSURE

### Technical Problem

The present invention has been made in an effort to provide a wideband electromagnetic wave shielding film having advantages of improved electromagnetic wave shielding and absorption performance, by applying a multilayer graphene-nanotube-metal oxide nanostructure in which a conductive material and a magnetic material are complexly combined by microwave irradiation, as a polymer filler.

### Technical Solution

An exemplary embodiment of the present invention provides an electromagnetic wave shielding film including a polymer and a filler dispersed in the polymer, wherein the filler includes a nanostructure including multilayer graphene; nanotubes disposed between layers or on a surface of the multilayer graphene and connected to the graphene; and a metal oxide connected to the nanotubes. The metal oxide of the nanostructure may include oxides of one or more metals selected from the group consisting of Ti, Zn, Sn, In, Al, Fe, Co, Ni, Cr, V, Ir, Ru, Mo, and a combination thereof. It is preferred that the metal oxide of the nanostructure includes oxides of one or more metals selected from the group consisting of iron, nickel and cobalt.

The polymer may include one or more polymers selected from the group consisting of poly(3,4-ethylenedioxythiophene)-poly(styrenesulfonate) (PEDOT:PSS), polyaniline, polypyrrole, polythiophene, polyethylene, polypropylene, polystyrene, polyalkyleneterephthalate, a polyamide resin, a polyacetal resin, polycarbonate, polysulfone and polyimide.

The nanostructure may be prepared by a method including: mixing a graphene oxide, an organometallic compound containing one or more magnetic particles and a foaming agent in a solvent to prepare a dispersion; and irradiating the dispersion with microwaves.

The organometallic compound may include oxides of one or more metals selected from the group consisting of Ti, Zn, Sn, In, Al, Fe, Co, Ni, Cr, V, Ir, Ru, Mo, and a combination thereof.

As the organometallic compound, metal oxides containing one or more magnetic particles selected from the group consisting of iron, nickel, cobalt, permalloy, sendust and ferrite powders may be used.

The graphene oxide and the organo-metal oxide may be used at a content of a weight ratio of 1:0.1 to 5.0.

The foaming agent may be one or more selected from the group consisting of azodicarbonamide, oxy-bis-benzene-sulfonylhydrazide, toluenesulfonyl-hydrazide, benzenesulfonyl-hydrazide, toluenesulfonyl-semicarbazide, 5-phenyltetrazole, and 2,4-dinitrophenyl 2-thiophenecarboxylate.

The graphene oxide and the foaming agent may be used at a content of a weight ratio of 1:0.05 to 0.5.

Another embodiment of the present invention provides an electromagnetic wave shielding film including a filler which is a multilayer graphene-nanotube-metal oxide nanostructure, and a composite material of a polymer.

Since the shielding film may include the constitution as described above, the multilayer graphene-nanotube-metal oxide nanostructure includes oxides of one or more metals selected from the group consisting of Ti, Zn, Sn, In, Al, Fe, Co, Ni, Cr, V, Ir, Ru, Mo, and a combination thereof.

The polymer may include one or more polymers selected from the group consisting of poly(3,4-ethylenedioxythiophene)-poly(styrenesulfonate) (PEDOT:PSS), polyaniline, polypyrrole, polythiophene, polyethylene, polypropylene, polystyrene, polyalkyleneterephthalate, a polyamide resin, a polyacetal resin, polycarbonate, polysulfone and polyimide.

In addition, the filler may be included at a content of 1 to 40 wt %, based on a total weight of the film.

### Advantageous Effects

According to the present invention, a wideband electromagnetic wave shielding film based on a polymer may be provided by preparing a three-dimensional multilayer graphene-nanotube-metal oxide nanostructure in which a conductive material and a magnetic material are complexly combined, and then applying this nanostructure as a polymer filler. Accordingly, the present invention may provide a film which is flexible and has durability and high shielding efficiency, and thus, is suitable for being used as a shielding material in wearable electronics, flexible device and the like.

### DESCRIPTION OF THE DRAWINGS

FIG. 1 illustrates an interaction mechanism between a multilayer graphene-nanotube-metal oxide nanostructure and a conductive polymer included in the electromagnetic wave shielding film according to an exemplary embodiment of the present invention.

FIG. 2 is a schematic diagram showing a multilayer graphene-nanotube-metal oxide nanostructure 100, in a polymer-based, wideband electromagnetic wave shielding film including a multilayer graphene-nanotube-metal oxide nanostructure.

FIG. 3 is a multilayer graphene-nanotube-metal oxide nanostructure synthesis method using microwaves.

FIG. 4 is scanning electron microscope (SEM) photographs of a multilayer graphene-nanotube-metal oxide nanostructure.

FIG. 5 is enlarged drawings of the multilayer graphene-nanotube-metal oxide nanostructure of FIG. 4, which are scanning electron microscope (SEM) photographs (a,b,c,d) and high resolution transmission electron microscope (TEM) photographs (e,f) of the nanostructure.

FIG. 6A represents comparison of overall shielding efficiency for a polymer-based, wideband electromagnetic wave shielding film including the multilayer graphene-nanotube-metal oxide of Example 1, and conventional electromagnetic wave shielding films of Comparative Examples 1 and 2.

FIG. 6B represents comparison of absorption shielding efficiency for a polymer-based, wideband electromagnetic wave shielding film including the multilayer graphene-nanotube-metal oxide of Example 1, and conventional electromagnetic wave shielding films of Comparative Examples 1 and 2.

FIG. 6C represents comparison of reflective shielding efficiency for a polymer-based, wideband electromagnetic wave shielding film including the multilayer graphene-nanotube-metal oxide of Example 1, and conventional electromagnetic wave shielding films of Comparative Examples 1 and 2.

FIG. 6D represents shielding efficiency before and after 1,000 cycle bending for a polymer-based, wideband electromagnetic wave shielding film including the multilayer graphene-nanotube-metal oxide nanostructure of Example 1.

### MODE FOR INVENTION

Hereinafter, referring to accompanying drawings, the exemplary embodiments of the present application will be described in detail, so that a person with ordinary skill in the art to which the present application pertains may easily practice them.

However, the present application may be implemented in various different forms, and is not limited to the exemplary embodiment and Examples described herein. Further, in the drawings, in order to clearly describe the present application, the parts not related to the description will be omitted, and throughout the specification, like parts are given like reference numerals.

Throughout the specification of the present application, unless explicitly described to the contrary, the word “comprise” and variations such as “comprises” or “comprising”, will be understood to imply the inclusion of stated elements but not the exclusion of any other elements.

The terms, “about”, “substantially” and the like used throughout the specification of the present application have the meaning at or close to the numerical value, when preparation and material tolerances unique to the mentioned meaning are suggested, and are used in order to prevent an unscrupulous infringer from improperly using the disclosure mentioning an accurate or absolute numerical value in order to facilitate understanding of the present invention.

Hereinafter, the electromagnetic wave shielding film of the preferred multilayer graphene-nanotube-metal oxide nanostructure of the present invention will be described in more detail.

The present invention may include, as described below, synthesizing a multilayer graphene-nanotube-metal oxide nanostructure using a microwave irradiation method, and using the multilayer graphene-nanotube-metal oxide nanostructure as a filler of a polymer to mix it with the polymer and then drying the mixture to manufacture a film.

Electromagnetic Wave Shielding Film

According to an embodiment of the present invention, an electromagnetic wave shielding film including a polymer, and a filler dispersed in the polymer, wherein the filler includes a nanostructure including multilayer graphene; nanotubes disposed between layers or on a surface of the multilayer graphene and connected to the graphene; and a metal oxide connected to the nanotubes, is provided.

In the specification of the present invention, the nanostructure refers to “a three-dimensional nanostructure as a multilayer graphene-nanotube-metal oxide nanostructure”.

Therefore, according to another exemplary embodiment of the present invention, an electromagnetic wave shielding film including a filler which is a multilayer graphene-nanotube-metal oxide nanostructure, and a composite of a polymer, is included.

Specifically, in the present invention, a wideband electromagnetic wave shielding film having improved electromagnetic wave shielding and absorption performance, by inserting and dispersing a polymer in a filler by interaction between the filler and the polymer, by applying the multilayer graphene-nanotube-metal oxide nanostructure as a filler of a polymer, may be provided. The electromagnetic wave shielding film of the present invention represents excellent and outstanding shielding efficiency overall from a 2.2 GHz band (mobile phone and communication device main use band) to X-band (8-12 GHz, radar and military communications use band), and thus, has a characteristic of wideband. Accordingly, the present invention may show an effect of shielding electromagnetic waves of various devices by adjusting a thickness depending on the desired band.

The electromagnetic wave shielding film (EMI film) of the present invention is a composite including a polymer with a nanostructure prepared by the above-described method at a certain ratio, and even in the case that repetitive mechanical deformation proceeds, it represents excellent restoring force, and in particular, may provide an effect of excellent flexibility and durability. Therefore, the present invention may implement flexibility, high mechanical rigidity and strength of a very thin, electromagnetic wave shielding film. Further, since the nanostructure included in the shielding film of the present invention is a light nanomaterial, it may contribute to a reduced thickness of a film, and also a reduced weight of an element to which it is applied.

Accordingly, the electromagnetic wave shielding film may be used in various purposes for blocking electromagnetic waves harmful to the human body, and for blocking electromagnetic waves causing a device malfunction. Specifically, since the electromagnetic wave shielding film represents excellent flexibility, it is used in a wearable electronic device to protect the human body from electromagnetic waves. In addition, the electromagnetic wave shielding film is used in medical equipment, aircrafts, radars and the like to significantly reduce a device malfunction caused by electromagnetic waves.

Accordingly, when a polymer is mixed with the filler which is a nanostructure of the present application at a certain ratio, the polymer is diffused in the nanostructure, and then a π-π interaction occurs between these two components to form a bond. As a chain structure of the polymer is changed from a coil shape to a linear shape due to the bonding, the polymer may be disposed between three-dimensional nanostructures to improve conductivity.

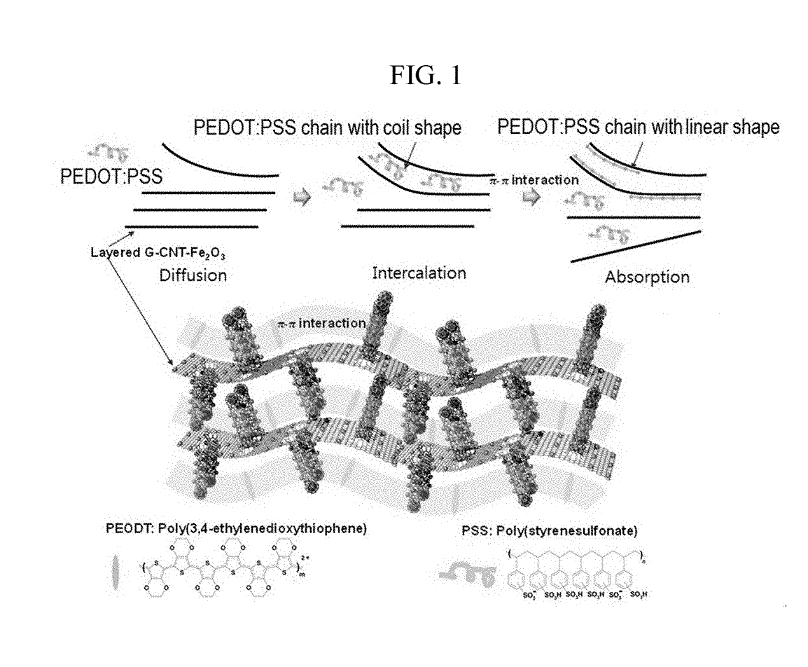

As the most preferable example, a conductive polymer such as PEDOT:PSS is used among the polymers, as shown in FIG. 1.

In FIG. 1, the structure of a PEDOT:PSS chain is changed from a coil shape to a linear shape between the PEDOT:PSS and 3D G-CNT-Fe₂O₃. When the 3D G-CNT-Fe₂O₃ and the PEDOT:PSS are mixed, a PEDOT polymer chain is attached to a surface of the layered 3D G-CNT-Fe₂O₃. Both coil and extended coil shapes are present in an original PEDOT:PSS thin film, but when a 3D G-CNT-Fe₂O₃ nanostructure is added to the PEDOT:PSS film as a filler, a linear or extended coil shape is predominant. The π-π interaction between 3D G-CNT-Fe₂O₃ and PEDOT:PSS forms a firmly coated layer on hexagonal carbon crystals. Further, the nanostructure of well-stacked and multilayered 3D G-CNT-Fe₂O₃ is covered with a PEDOT:PSS matrix. This structural change may increase intrachain and interchain charge carrier mobility, thereby improving conductivity.

In the electromagnetic wave shielding film of the present invention, the nanostructure is a filler, and when added to a polymer (e.g., PEDOT:PSS) to form a film, it is preferred to set a use range so that the weight ratio of the filler in the resultant final film is 1 to 40 wt %. Accordingly, the filler may be included at 1 to 40 wt %, and the polymer may be used in a range of 60 to 99 wt %, based on a total weight of the film.

When the content of the nanostructure used as the filler is less than 1 wt %, it is difficult to express performance, and when more than 40 wt %, there may occur a dispersion problem.

Accordingly, only when the mixing ratio of the polymer satisfies the above range, the film thickness, shielding performance and conductivity to be desired may be effectively implemented without agglomerate of the nanostructure.

Most preferably, the mixing ratio of the nanostructure and the composite material of a polymer is a weight ratio of 1:9.

In addition, in manufacturing a composite material film, any polymer may be used as long as it is a polymer having conductivity, commonly known in the art. Accordingly, not only a common conductive polymer but also a thermoplastic resin and the like may be used. The thermoplastic resin which is a semi-crystalline resin occupies a crystal region of the composite material to push a hybrid filler to the outside, thereby forming a conductive pass better than a non-crystalline resin, and thus, may be used as a conductive polymer. A preferred example of this polymer may include a polymer such as poly(3,4-ethylenedioxythiophene)-poly(styrenesulfonate), PEDOT:PSS. The thermoplastic resin may be one or more selected from the group consisting of polyethylene, polypropylene, polystyrene, polyalkyleneterephthalate, a polyamide resin, a polyacetal resin, polycarbonate, polysulfone and polyimide. More preferably, the polymer may include one or more conductive polymers selected from the group consisting of poly(3,4-ethylenedioxythiophene)-poly(styrenesulfonate) (PE DOT: PSS), polyaniline, polypyrrole and polythiophene.

Further, when using the polymer, it may be dispersed in a commonly well-known solvent such as DMSO capable of dispersing the polymer well, and thus, the solvent is not limited.

The metal oxide of the nanostructure may include oxides of one or more metals selected from the group consisting of Ti, Zn, Sn, In, Al, Fe, Co, Ni, Cr, V, Ir, Ru, Mo, and a combination thereof. Most preferably, the metal oxide of the nanostructure may include oxides of one or more metals selected from the group consisting of iron, nickel, cobalt, permalloy, sendust and ferrite powders. Accordingly, the multilayer graphene-nanotube-metal oxide nanostructure may include oxides of one or more metals selected from the group consisting of Ti, Zn, Sn, In, Al, Fe, Co, Ni, Cr, V, Ir, Ru, Mo, and a combination thereof.

This electromagnetic wave shielding film has a very small thickness, and shows excellent durability and excellent flexibility. The shielding film of the present invention may have a thickness changeable depending on various uses, and has a characteristic of having better shielding efficiency, even in the case of having a very small thickness. As an example, the electromagnetic wave shielding film shows opaqueness, and may have a thickness of 1 μm to 10 mm. Most preferably, the electromagnetic wave shielding film may have a thickness of 50 μm to 1 mm.

Multilayer Graphene-Nanotube-Metal Oxide Nanostructure

As described above, the multilayer graphene-nanotube-metal oxide nanostructure intended to be provided in the present invention has a three-dimensional structure, and is an electromagnetic wave shielding nanomaterial being light and capable of improving electromagnetic wave shielding and absorption performance, as compared with a conventional material, by complexly combining a conductive material and a magnetic material in the structure by microwave irradiation. Accordingly, the present invention provides an effect of greatly improving electromagnetic wave shielding and absorption performance, by applying the nanomaterial with the polymer to the shielding film.

This nanostructure has a three-dimensional structure including multilayer graphene; nanotubes disposed between layers or on a surface of the multilayer graphene, and connected to the graphene; and a metal oxide connected to the nanotubes. Accordingly, the nanostructure is used as a filler of the polymer, thereby obtaining a composite material in which the polymer is stably disposed in the filler.

According to a preferred exemplary embodiment of the present invention, the nanostructure may be prepared by a method including: mixing a graphene oxide, an organometallic compound containing one or more magnetic metals and a foaming agent in a solvent to prepare a dispersion; and irradiating the dispersion with microwaves.

The graphene oxide used in the step of preparing the dispersion may be formed by being exfoliated from a graphite oxide. According to a preferred exemplary embodiment of the present invention, the graphene oxide exfoliated from the graphite oxide may be provided by a method of exfoliating a graphene oxide from high-purity graphite using a modified Hummer's method.

For example, in the present invention, the graphite oxide is prepared by using graphite powder, an alkali metal salt and a solvent, and the graphene oxide may be exfoliated from the graphite oxide through neutralization and homogeneous agitation of the graphite oxide.

The alkali metal salt may be used as an oxidant, and as an example thereof, any one or more selected from the group consisting of sodium nitrate, potassium permanganate, potassium chlorate and potassium hypochlorite may be used. The alkali metal salt may be used in an amount of 2 to 5 parts by weight, based on 1 part by weight of the graphite powder.

The solvent may be nitric acid, sulfuric acid, hydrochloric acid or a mixture thereof, and may be used in an amount of 0.5 to 2 parts by weight, based on 1 part by weight of the graphite powder.

In manufacturing the multilayer graphene-nanotube-metal oxide nanostructure, the organo-metal oxide may contain magnetic particles such as iron, nickel, cobalt and the like.

The organo-metal oxide is a carbon compound containing one or more magnetic particles, and may be used as a precursor for forming the metal oxide. The magnetic particles may include metals having excellent magnetic permeability. This organometallic compound may include oxides of metals selected from the group consisting of Ti, Zn, Sn, In, Al, Fe, Co, Ni, Cr, V, Ir, Ru, Mo, and a combination thereof, but not limited thereto. More preferably, the organometallic compound may be metal oxides containing one or more magnetic particles selected from the group consisting of iron, nickel, cobalt, permalloy, sendust and ferrite powders. More specific example of the organometallic compound may be one or more selected from the group consisting of ferrocene, nickelocene and cobaltocene.

The graphene oxide and the organo-metal oxide may be used at a content of a weight ratio of 1:0.1 to 5.0. When the weight ratio of the organo-metal oxide is less than 1:0.1, the organo-metal oxide does not serve as a catalyst properly, so that a structure growth yield drops sharply, and when the weight ratio of the organo-metal oxide is more than 1:5, agglomerate between the organo-metal oxides occurs, so that a structure growth yield drops sharply.

The foaming agent may be one or more selected from the group consisting of azo di-carbonamide (ADC), oxy-bis-benzene-sulfonylhydrazide (OBSH), toluenesulfonyl-hydrazide (TSH), benzenesulfonyl-hydrazide (BSH), toluenesulfonyl-semicarbazide (TSH), 5-phenyltetrazole (5-PT) and 2,4-dinitrophenyl 2-thiophenecarboxylate (DNPT). The graphene oxide and the foaming agent may be used at a weight ratio of 1:0.05 to 0.5. More preferably, the graphene oxide and the foaming agent may be used at a content of a weight ratio of 1:0.1 to 0.5, or a weight ratio of 1:0.1 to 0.3. When the foaming agent is used at a weight ratio range less than 1:0.05 relative to the graphene oxide, the content of the foaming agent is too small, so that expansion in a thickness direction of the graphene oxide is unlikely to occur. Further, when the ratio is at a weight ratio more than 1:0.5, there may occur explosion. Accordingly, when the ratio is within the above range, efficiency of stably separating the graphene oxide into graphene may be increased.

Accordingly, in an exemplary embodiment of the present invention, it is most preferred that the graphene oxide (GO), the organometallic compound, and the foaming agent are used at a weight ratio of 1:1:0.1.

Meanwhile, the dispersion may be prepared using an organic solvent, and the kind of organic solvent is not particularly limited, and materials well known in the art may be used as the organic solvent. For example, the organic solvent may be polar aprotic solvents, alcohols, aromatic hydrocarbons, and the like, and specifically, acetonitrile, ethylacetate, ethanol, acetone, benzene, toluene and the like may be used, but not limited thereto.

In order to carry out the step of irradiating the dispersion with microwaves, the microwaves may be irradiated at intensity of 300 W to 1,000 W for 1 second to 1,000 seconds. Here, when the microwaves are irradiated for less than 1 second, doping of a functional group such as sulfur and nitrogen to graphene is not done well, and a residual functionalized graphene oxide remains to degrade electrochemical performance, and when irradiation is carried out for more than 1000 seconds, carbon-based graphene burns to be changed into a carbon dioxide form, and eventually the graphene structure may disappear.

Further, in the step of irradiating the dispersion with microwaves, the foaming agent may generate gas, and the gas may be inserted between a plurality of layers of graphite oxide to cause expansion in a thickness direction of graphite oxide. Here, the gas may be, for example, nitrogen gas, carbon monoxide, carbon dioxide, urea gas, ammonia and the like.

Specifically, when the dispersion is irradiated with microwaves, the foaming agent inserted into the graphene oxide is decomposed to generate gas such as nitrogen gas, carbon monoxide, carbon dioxide, urea gas and ammonia, and by this gas, rapid expansion of graphene oxide in a thickness direction (vertical) may occur. Further, the organometallic compound included in the dispersion may form a metal oxide.

Accordingly, graphene worm representing significant exfoliation of the graphene oxide in a thickness direction may be formed.

Meanwhile, gas generated when the foaming agent is decomposed may serve as a reducing agent to reduce the graphene oxide to graphene without an additional reducing agent. Accordingly, reduction to graphene without an additional reducing agent such as hydrazine may be carried out, so that the process may be simplified and environmental-friendly.

Further, according to the present invention, for particle pulverization and dispersion of the dispersion, a step of ultrasonication may be further included, before the step of irradiating the dispersion with microwaves.

The ultrasonication may be carried out for example, at about 20 to 100 Hz for about 1 minute to 50 minutes.

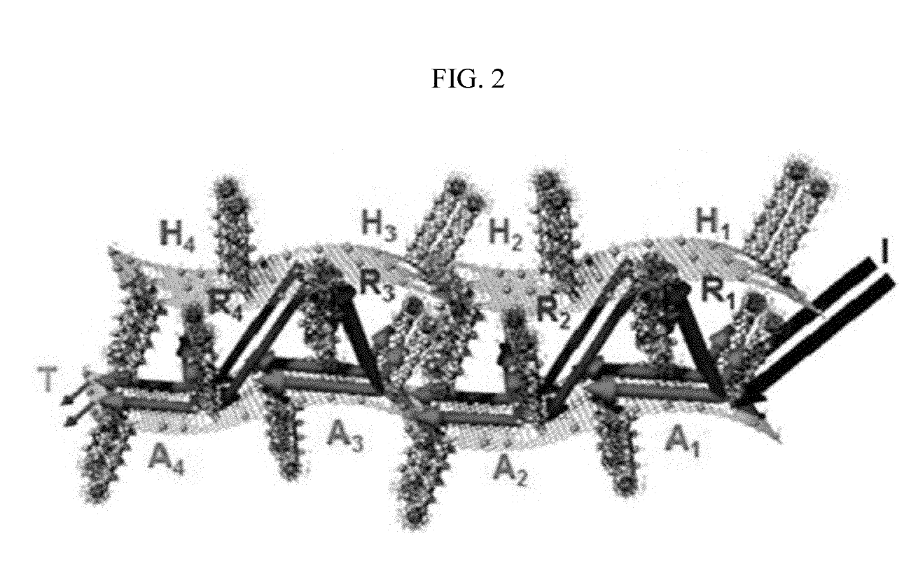

This multilayer graphene-nanotube-metal oxide nanostructure may represent the structure of FIG. 2.

FIG. 2 is a schematic diagram showing a multilayer graphene-nanotube-metal oxide nanostructure 100, in a polymer-based, wideband electromagnetic wave shielding film including a multilayer graphene-nanotube-metal oxide nanostructure.

As shown in FIG. 2, the multilayer graphene-nanotube-metal oxide nanostructure 100 according to the present invention is a three-dimensional structure, and is formed of a structure including a carbon nanotube 101, a metal oxide 102 and a graphene 103.

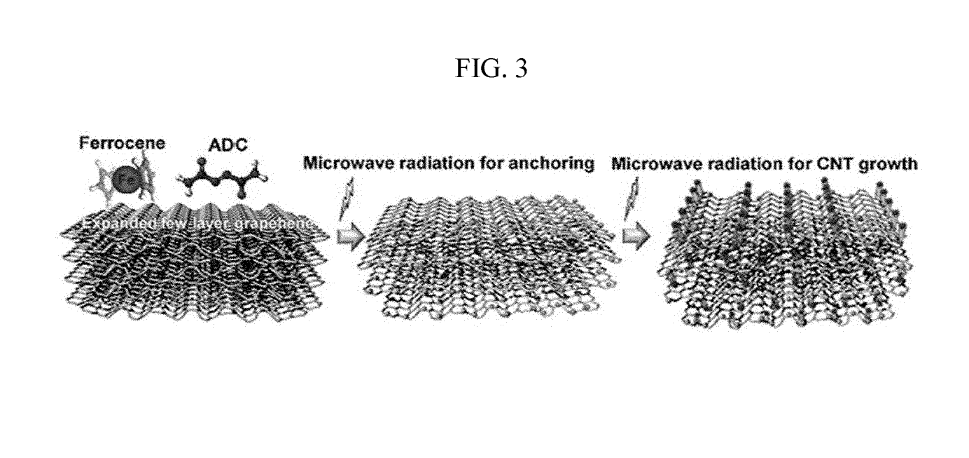

Further, the multilayer graphene-nanotube-metal oxide nanostructure of the present invention may be prepared by the above-described steps. FIG. 3 schematically represents a synthesis method of a multilayer graphene-nanotube-metal oxide nanostructure using microwaves.

As shown in FIG. 3, after a graphene oxide, an organometallic compound (e.g., ferrocene), and a foaming agent (e.g., ADC) are combined, when microwaves are irradiated, growth of CNT is promoted vertically on graphene, so that a heterostructure is shown, and density thereof may be increased. Further, the multilayer graphene-nanotube-metal oxide nanostructure may include oxides of one or more metals selected from the group consisting of iron, nickel and cobalt.

Hereinafter, the effects of the invention will be described in more detail, by the specific Examples of the invention. However, the following Examples are only suggested as an example of the invention, and the managed scope of the invention is not limited thereto.

### Preparation Example 1

Synthesis of Graphene Oxide

First, a graphene oxide should be exfoliated from high-purity graphite, using a modified Hummer's method.

For this, 0.5 g of graphite (Samjung C&C, 99.95%, average size 200 μm) was added to 15 ml of sulfuric acid (H₂SO₄), and mixing was carried out by agitation at room temperature for 15 minutes.

Subsequently, 0.5 g of potassium permanganate (KMnO₄) was slowly added to the mixed solution for 30 minutes. At that time, the solution was agitated in an ice bath.

Thereafter, the mixed solution was agitated in water at 50° C. for four hours.

Then, 150 ml of deionized water and 10 ml of hydrogen peroxide (H₂O₂) were added thereto and agitated for 30 minutes.

Further, a graphite oxide was neutralized by filtration, and a graphene oxide was exfoliated from the graphite oxide using a homogenizer.

Then, the graphene oxide was collected using a centrifuge and dried in an oven.

Synthesis of Multilayer Graphene-Nanotube-Metal Oxide Nanostructure

The graphene oxide collected in the above method was subjected to the following microwave irradiation method to synthesize a multilayer graphene-nanotube-metal oxide nanostructure (see FIG. 2).

0.1 g of graphene oxide, 0.1 g of ferrocene (Fe(C₅H₅)₂, 98%), and 0.01 g of azodicarbonamide (foaming agent) were added to 10 ml of acetonitrile, and mixed, and then, subjected to sonication for 30 minutes to be uniformly dispersed.

Further, the dispersion mixture was irradiated with microwaves at an output of 700 W for 1 minute in a microwave reactor to simply prepare a multilayer graphene-nanotube-metal oxide nanostructure (3D G-CNT-Fe₂O₃).

### Example 1

Manufacture of Polymer-Based Electromagnetic Wave Shielding Film Including Multilayer Graphene-Nanotube-Metal Oxide Nanostructure (Multilayered 3D G-CNT-Fe₂O₃)

PEDOT:PSS (poly(3,4-ethylenedioxythiophene) polystyrene sulfonate) and DMSO were mixed at a weight ratio of 98/2 to prepare a PEDOT:PSS water-soluble dispersion.

The multilayer graphene-nanotube-metal oxide nanostructure (3D G-CNT-Fe₂O₃) prepared in Preparation Example 1 and the PEDOT:PSS water-soluble dispersion were mixed at a weight ratio of 1:9, and then subjected to sonication for 30 minutes to be uniformly dispersed.

When dispersion was completed, the dispersion was poured to a petri dish, and dried (cured) in an oven at 40° C. for 12 hours, thereby obtaining a flexible electromagnetic wave shielding film.

### Comparative Example 1

A film formed of only PEDOT:PSS, which is a conductive polymer prepared by a common method was used in Comparative Example 1.

### Comparative Example 2

Preparation of Composite Material of 2D rGO+PEDOT:PSS

A film was prepared in the same manner as in Example 1, except that a reduced graphene oxide (2D rGO) obtained by a common method was used, instead of the multilayer graphene-nanotube-metal oxide nanostructure of Preparation Example 1.

### Comparative Example 3

Preparation of Composite Material of 2D G-Fe₂O₃+PEDOT:PSS

A film was obtained in the same manner as in Example 1, except that a two-dimensional graphene-metal oxide structure (2D G-Fe₂O₃) was used, instead of the multilayer graphene-nanotube-metal oxide nanostructure of Preparation Example 1.

### Experimental Example 1

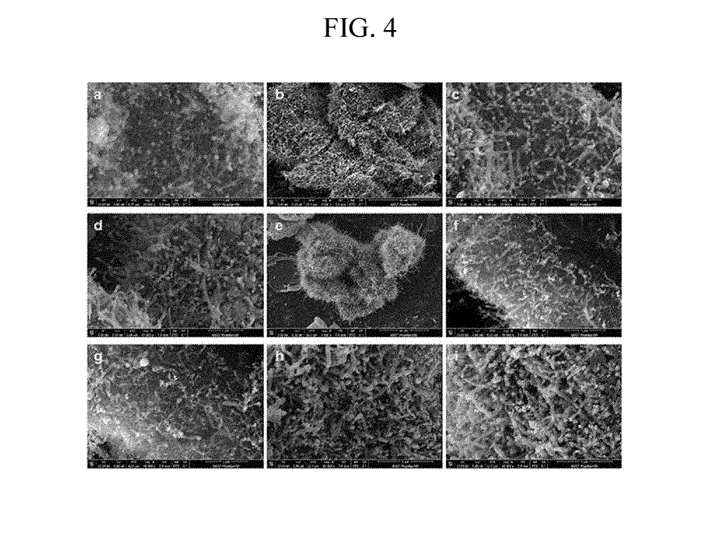

The photographs of the multilayer graphene-nanotube-metal oxide nanostructure (3D G-CNT-Fe₂O₃) of Preparation Example 1 were taken by a scanning electron microscope (SEM), and the result is shown in FIG. 4. In FIG. 4, a to i refer to images of identifying one nanostructure with multiple angles. That is, b and e are enlarged in a microscale, and the rest images are the results of identifying the detailed structure enlarged in a nanoscale.

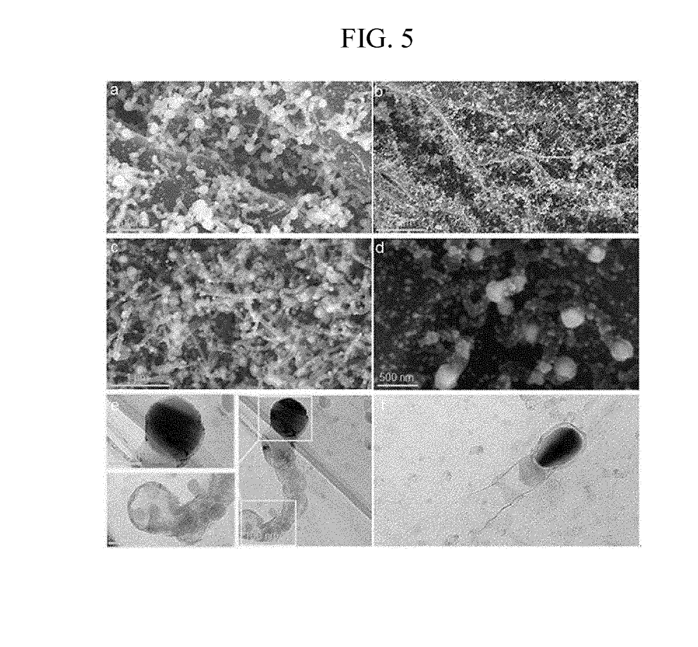

In addition, the scanning electron microscope (SEM) photographs (a,b,c,d) and the high-resolution transmission electron microscope (TEM) photographs (e,f) of the multilayer graphene-nanotube-metal oxide nanostructure (3D G-CNT-Fe₂O₃) were taken and the result is shown in FIG. 5 by comparison. FIG. 5 is enlarged drawings of FIG. 4, in which a and b are drawings for identifying the multi-layer of the multilayer graphene-nanotube-metal oxide nanostructure, c is a drawing for identifying that nanotubes synthesized in a long shape are tangled like a nest, and d, e and f are drawings for identifying that the composite material film of the present application is not a mixture, but has a structure in which CNTs and a metal oxide are all connected to a graphene oxide (GO). (SEM image: (a) a multilayered 3D G-CNT-Fe₂O₃ hetero structure, (b) a multilayered 3D G-CNT-Fe₂O₃ hetero structure in a large scale, (c) an interconnection type 1: a cross-linked structure with CNTs, (d) an interconnection type 2: graphene intercalation CNT, TEM image: (e and f) an interconnection type 2: graphene intercalation CNT)

From the results of FIGS. 4 and 5, it was confirmed that in the multilayer graphene-nanotube-metal oxide nanostructure (3D G-CNT-Fe₂O₃) of the present invention, a three-dimensional heterostructure in a microscale and high-density CNTs are anchored vertically on a surface of the graphene.

### Experimental Example 2

Setup for Measuring Electromagnetic Wave Shielding Effect

A scattering parameter (S21) between face-to-face connected, two waveguide-to-coaxial adapters was measured by using Agilent N5230A (bandwidth: 300 kHz to 20 GHz). In addition, in order to perform measurement in a frequency range of 2.2 to 3.3 GHz, 3.3 to 4.9 GHz, 4.9 to 8.0 GHz, and X-band (8.0 to 12 GHz), the sample was cut into pieces of 100 mm×90 mm, 80 mm×70 mm, 70 mm×60 mm and 50 mm×35 mm for using. Further, the thickness of all samples was 0.1 mm.

(1) Electromagnetic Wave Shielding Performance Test

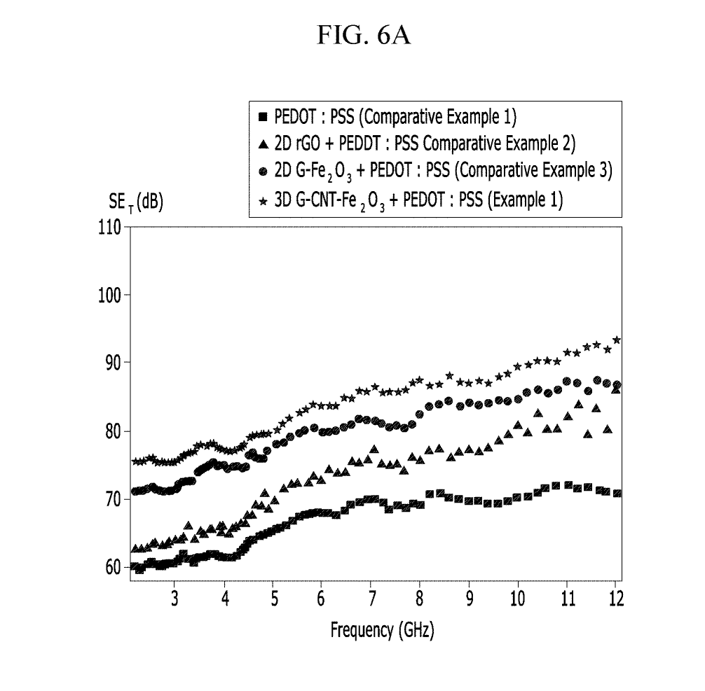

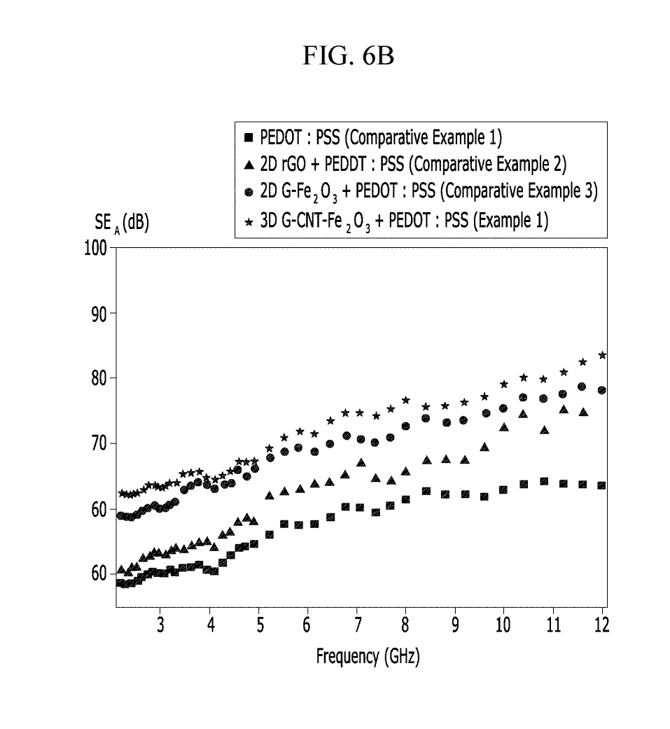

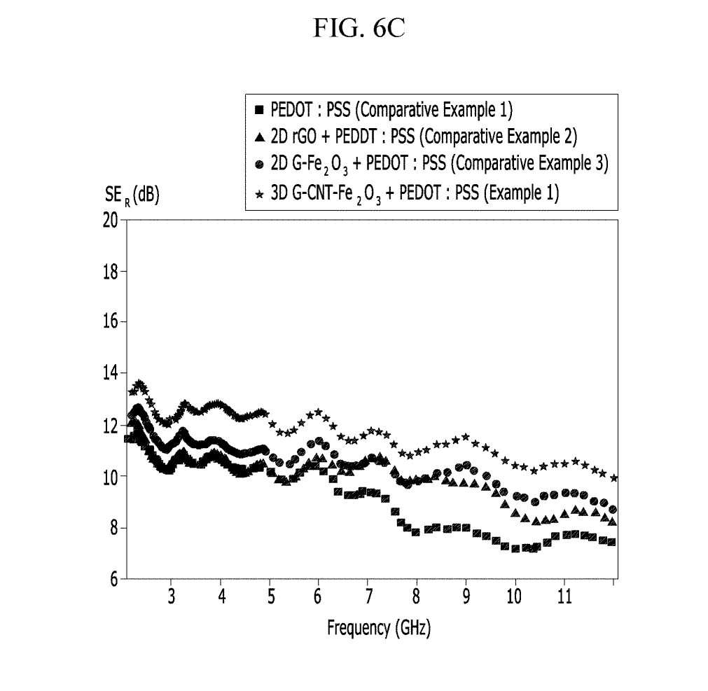

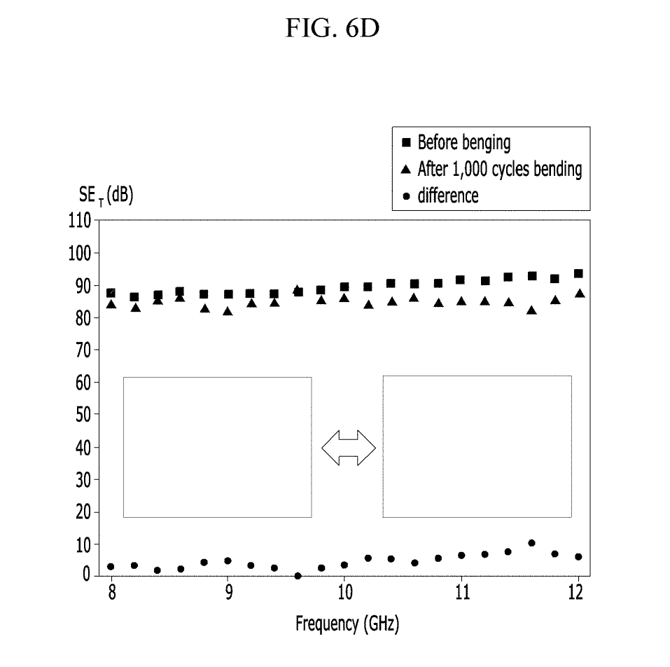

The electromagnetic wave shielding efficiency (EMI shielding effectiveness (SE)), the absorption shielding efficiency and the reflection shielding efficiency of the electromagnetic wave shielding films of Example 1 and Comparative Examples 1-3 were measured by using the above method. The results are shown in FIGS. 6A to 6C.

Further, for the electromagnetic wave shielding film of Example 1, shielding efficiency before and after 1,000 cycle bending was measured, and the result is shown in FIG. 6D.

In FIGS. 6A to 6d, electromagnetic wave shielding efficiency (SE) is defined as a ratio of incident energy, and represented by the following Equation 1:

SEₜₒₜₐₗ=10 log(P₀/Pᵢ)=20 log(E₀/Eᵢ)=SE_{R}+SE_{A}+SE_{M} (dB) [Equation 1]

wherein Pᵢ(Ei) and P₀(Eo) are power (electric field) of incident, and transmitted EM waves, respectively; and SE represents an individual contribution level of reflection (SER), absorption (SEA) and multiple reflection (SEM), calculated by dB.

As shown in FIGS. 6A to 6C, it is recognized that the electromagnetic wave shielding and absorption performance of the film of Example 1 of the present invention is much superior to that of Comparative Examples 1 to 3.

Further, as seen from FIG. 6D, the shielding film of Example 1 had a very good shielding effect even after 1,000 cycle bending. Accordingly, the present invention may provide a film having excellent flexibility and durability, and thus, may be used as a shielding material in wearable electronics, flexible devices, and the like.

### Experimental Example 3

(1) Conductivity Test 1 (Before and after 1,000 Cycle Bending)

For Example 1 and Comparative Examples 1-3, conductivity before and after 1,000 cycle bending was measured (radius 2.0 mm), and the results are shown in Table 1:

TABLE 1

| | | Sheet | | Change |
|---|---|---|---|---|
| | | resistance | Conductivity | rate (A/B) |
| | Material | (Ohm/sq) | (S/cm) | (%) |
| Before | (Example1) | 0.0969 | 227.8127 | |
| bending (A) | 3D | | | |
| | G-CNT-Fe₂O₃ + PEDOT:PSS | | | |
| | (Comparative Example1) | 0.1430 | 154.3710 | |
| | PEDOT:PSS | | | |
| | (Comparative Example2) | 0.1361 | 162.1973 | |
| | 2D rGO + PEDOT:PSS | | | |
| | (Comparative Example3) | 0.1190 | 185.5047 | |
| | 2D G-Fe₂O₃ + PEDOT:PSS | | | |
| After 1,000 | (Example1) | 0.1075 | 205.3474 | 90.14% |
| cycle bending | 3D | | | |
| (B) | G-CNT-Fe₂O₃ + PEDOT:PSS | | | |
| | (Comparative Example1) | 0.1597 | 138.2283 | 89.54% |
| | PEDOT:PSS | | | |
| | (Comparative Example2) | 0.1497 | 147.4620 | 90.92% |
| | 2D rGO + PEDOT:PSS | | | |
| | (Comparative Example3) | 0.1309 | 168.6406 | 90.91% |
| | 2D G-Fe₂O₃ + PEDOT:PSS | | | |

From Table 1, it is recognized that Example 1 of the present invention had sheet resistance, conductivity and conductivity change rates before and after 1,000 cycle bending which are all excellent, as compared with Comparative Examples 1 to 3. Further, Example 1 showed less change rates of the physical properties even after 1,000 cycle bending, and thus, was confirmed to represent excellent restoring force, flexibility and durability.

(2) Conductivity Test 2

A graphene-CNT-Fe₂O₃ mixture including reduced graphene oxide (rGO), CNT and Fe₂O₃ obtained by a common method was used to compare with Example 1, in terms of conductivity and an electromagnetic wave shielding effect. The results are shown in Table 2. Here, the test was carried out by changing the mixing ratio of the oxide.

TABLE 2

| | Sheet | | SE@ |
|---|---|---|---|
| | resistance | Conductivity | 8-12 GHz |
| | (Ohm/sq) | (S/cm) | (dB) |
| (Example1) | 0.0969 | 227.8127 | 88.2-93.4 |
| 3D G-CNT-Fe₂O₃ + PEDOT:PSS | | | |
| rGO/CNT/Fe₂O₃ mixture (6:2:2) | 0.1352 | 163.3374 | 77.8-82.9 |
| rGO/CNT/Fe₂O₃ mixture (5:3:2) | 0.1334 | 165.5422 | 79.5-82.9 |
| rGO/CNT/Fe₂O₃ mixture (4:4:2) | 0.1322 | 167.0454 | 77.5-83.1 |
| rGO/CNT/Fe₂O₃ mixture (3:5:2) | 0.1310 | 168.5762 | 78.2-82.9 |
| rGO/CNT/Fe₂O₃ mixture (2:6:2) | 0.1298 | 170.1353 | 77.1-84.4 |

From Table 2, it is recognized that the conductivity and electromagnetic wave shielding effect of Example 1 are much superior to those of the common graphene-CNT-Fe₂O₃ mixture.

From the above results, the electromagnetic wave shielding film of the present invention was shown to have excellent shielding efficiency to wideband electromagnetic waves, and thus, may be used in various uses for shielding electromagnetic waves harmful to the human body, and in various uses for shielding electromagnetic waves causing a device malfunction.

### DESCRIPTION OF SYMBOLS

100: Multilayer graphene-nanotube-metal oxide nanostructure
101: Carbon nanotube
102: Metal oxide
103: Graphene

1. An electromagnetic wave shielding film, comprising a polymer and a filler dispersed in the polymer,
wherein the filler includes a nanostructure including multilayer graphene; nanotubes disposed between layers or on a surface of the multilayer graphene and connected to the graphene; and a metal oxide connected to the nanotubes.

2. The electromagnetic wave shielding film of claim 1,
wherein the metal oxide of the nanostructure includes oxides of one or more metals selected from the group consisting of Ti, Zn, Sn, In, Al, Fe, Co, Ni, Cr, V, Ir, Ru, Mo, and a combination thereof.

3. The electromagnetic wave shielding film of claim 1,
wherein the metal oxide of the nanostructure includes oxides of one or more metals selected from the group consisting of iron, nickel and cobalt.

4. The electromagnetic wave shielding film of claim 1,
wherein the polymer includes one or more polymers selected from the group consisting of poly(3,4-ethylenedioxythiophene)-poly(styrenesulfonate) (PEDOT:PSS), polyaniline, polypyrrole, polythiophene, polyethylene, polypropylene, polystyrene, polyalkyleneterephthalate, a polyamide resin, a polyacetal resin, polycarbonate, polysulfone and polyimide.

5. The electromagnetic wave shielding film of claim 4,
wherein the polymer includes one or more conductive polymers selected from the group consisting of poly(3,4-ethylenedioxythiophene)-poly(styrenesulfonate) (PEDOT:PSS), polyaniline, polypyrrole and polythiophene.

6. The electromagnetic wave shielding film of claim 1,
wherein the filler is comprised at a content of 1 to 40 wt %, based on a total weight of the film.

7. The electromagnetic wave shielding film of claim 1,
wherein the nanostructure is prepared by a method including:
mixing a graphene oxide, an organometallic compound containing one or more magnetic particles and a foaming agent in a solvent to prepare a dispersion; and
irradiating the dispersion with microwaves.

8. The electromagnetic wave shielding film of claim 7,
wherein the organometallic compound includes oxides of metals selected from the group consisting of Ti, Zn, Sn, In, Al, Fe, Co, Ni, Cr, V, Ir, Ru, Mo, and a combination thereof.

9. The electromagnetic wave shielding film of claim 7,
wherein the organometallic compound includes metal oxides containing one or more magnetic particles selected from the group consisting of iron, nickel, cobalt, permalloy, sendust and ferrite powders.

10. The electromagnetic wave shielding film of claim 7,
wherein the graphene oxide and the organo-metal oxide are used at a content of a weight ratio of 1:0.1 to 5.0.

11. The electromagnetic wave shielding film of claim 7,
wherein the foaming agent is one or more selected from the group consisting of azodicarbonamide, oxy-bis-benzene-sulfonylhydrazide, toluenesulfonyl-hydrazide, benzenesulfonyl-hydrazide, toluenesulfonyl-semicarbazide, 5-phenyltetrazole, and 2,4-dinitrophenyl 2-thiophenecarboxylate.

12. The electromagnetic wave shielding film of claim 7,
wherein the graphene oxide and the foaming agent are used at a weight ratio of 1:0.05 to 0.5.

13. An electromagnetic wave shielding film, comprising a filler being a multilayer graphene-nanotube-metal oxide nanostructure, and a composite material of a polymer.

14. The electromagnetic wave shielding film of claim 13,
wherein the multilayer graphene-nanotube-metal oxide nanostructure includes oxides of one or more metals selected from the group consisting of Ti, Zn, Sn, In, Al, Fe, Co, Ni, Cr, V, Ir, Ru, Mo, and a combination thereof.

15. The electromagnetic wave shielding film of claim 13,
wherein the polymer includes one or more polymers selected from the group consisting of poly(3,4-ethylenedioxythiophene)-poly(styrenesulfonate) (PEDOT:PSS), polyaniline, polypyrrole, polythiophene, polyethylene, polypropylene, polystyrene, polyalkyleneterephthalate, a polyamide resin, a polyacetal resin, polycarbonate, polysulfone and polyimide.

16. The electromagnetic wave shielding film of claim 13,
wherein the filler is comprised at a content of 1 to 40 wt %, based on a total weight of the film.
